(19) United States
(12) Patent Application Publication
(10) Pub. No.: US 2025/0306128 A1
(43) Pub. Date: Oct. 2, 2025

(54) FRONT-STAGE OPEN-CIRCUIT DETECTION DEVICE AND METHOD THEREOF

(71) Applicant: Xiamen PVTECH Co., Ltd., Xiamen (CN)

(72) Inventors: HAO YE, Xiamen (CN); FUXING LU, Xiamen (CN); CHENGQUAN XU, Xiamen (CN)

(73) Assignee: Xiamen PVTECH Co., Ltd., Xiamen (CN)

(21) Appl. No.: 19/090,320

(22) Filed: Mar. 25, 2025

(30) Foreign Application Priority Data
Mar. 27, 2024 (CN) 202410362389.8

(51) Int. Cl. G01R 31/54; G01R 31/26; H05B 47/24

(52) U.S. Cl. CPC G01R 31/54; G01R 31/2635; H05B 47/24

(57) ABSTRACT

A front-stage open-circuit detection device includes an isolation transformer, an adjustment circuit, a voltage divider and a controller. The isolation transformer has a detection point, a primary side, and a secondary side. The detection point receives a control signal from the control switch of the converter in a lighting device. The primary side couples the control signal to the secondary side to generate a coupled signal. The adjustment circuit rectifies and filters the coupled signal to generate an adjusted signal. The voltage divider circuit divides the adjusted signal to generate a voltage signal. The controller receives the voltage signal and generates a state signal.

### BACKGROUND OF THE INVENTION

### 1. FIELD OF THE INVENTION

The present invention relates to an open-circuit detection circuit, in particular to a front-stage open-circuit detection circuit for lighting devices.

### 2. DESCRIPTION OF THE PRIOR ART

The currently available open-circuit detection method for light-emitting diode (LED) lighting devices involves adding a detection resistor to the rear stage of the lighting device and determining whether the LED lighting device is in the open-circuit state by measuring the voltage drop across the detection resistor. Although this method is simple, this method increases the power loss of the LED lighting device and reduces the efficiency thereof. Since the output power of LED lighting devices is relatively low, increasing the resistance value of the aforementioned resistor would lead to a particularly noticeable increase in power loss. Conversely, if the resistance value of the resistor is not increased, the voltage drop across the resistor would be too small, making it prone to erroneous measurements. Therefore, the currently available open-circuit detection method is not suitable for LED lighting devices.

### SUMMARY OF THE INVENTION

One embodiment of the present invention provides a front-stage open-circuit detection device, which includes an isolation transformer, an adjustment circuit, a voltage divider and a controller. The isolation transformer has a detection point, a primary side, and a secondary side. The detection point receives a control signal from the control switch of the converter in a lighting device. The primary side couples the control signal to the secondary side to generate a coupled signal. The adjustment circuit rectifies and filters the coupled signal to generate an adjusted signal. The voltage divider circuit divides the adjusted signal to generate a voltage signal. The controller receives the voltage signal and generates a state signal.

In one embodiment, the voltage divider circuit includes a main resistor and an auxiliary resistor. One end of the main resistor is connected to the adjustment circuit, the other end of the main resistor is connected to one end of the auxiliary resistor and the controller. The other end of the auxiliary resistor is connected to a grounding point.

In one embodiment, the auxiliary resistor is a variable resistor.

In one embodiment, the front-stage open-circuit detection device further includes an auxiliary capacitor. One end of the auxiliary capacitor is connected to the other end of the main resistor, one end of the auxiliary resistor, and the controller. The other end of the auxiliary capacitor is connected to the grounding point.

In one embodiment, the voltage signal generated by the voltage divider circuit causes the controller to read a voltage value substantially equal to the preset minimum measurement value of the controller when the lighting device enters the open-circuit state. The controller generates the state signal indicating the open-circuit state.

In one embodiment, the voltage signal generated by the voltage divider circuit causes the controller to read a voltage value greater than the preset minimum measurement value of the controller when the lighting device is connected to a load and enters the normal operating state. The controller generates the state signal indicating the normal operating state.

Another embodiment of the present invention provides a front-stage open-circuit detection method, which includes the following steps: receiving a control signal from the control switch of the converter in a lighting device via the detection point of an isolation transformer; coupling the control signal from the primary side of the isolation transformer to the secondary side of the isolation transformer to generate a coupled signal; rectifying and filtering the coupled signal via an adjustment circuit to generate an adjusted signal; dividing the adjusted signal via a voltage divider circuit to generate a voltage signal; and receiving the voltage signal through a controller to generate a state signal.

In one embodiment, the voltage divider circuit includes a main resistor and an auxiliary resistor. One end of the main resistor is connected to the adjustment circuit, and the other end of the main resistor is connected to one end of the auxiliary resistor and the controller. The other end of the auxiliary resistor is connected to a grounding point.

In one embodiment, the voltage signal generated by the voltage divider circuit causes the controller to read a voltage value substantially equal to the preset minimum measurement value of the controller when the lighting device enters the open-circuit state. The controller generates the state signal indicating the open-circuit state.

In one embodiment, the voltage signal generated by the voltage divider circuit causes the controller to read a voltage value greater than a preset minimum measurement value of the controller when the lighting device is connected to a load and enters the normal operating state. The controller generates the state signal indicating the normal operating state.

The front-stage open-circuit detection device and method thereof in accordance with the embodiments of the present invention may have the following advantages:

(1) In one embodiment of the present invention, the front-stage open-circuit detection device includes an isolation transformer, an adjustment circuit, a voltage divider and a controller. The isolation transformer has a detection point, a primary side, and a secondary side. The detection point receives a control signal from the control switch of the converter in a lighting device. The primary side couples the control signal to the secondary side to generate a coupled signal. The adjustment circuit rectifies and filters the coupled signal to generate an adjusted signal. The voltage divider circuit divides the adjusted signal to generate a voltage signal. The controller receives the voltage signal and generates a state signal. The circuit design of the front-stage open-circuit detection device can execute a specialized front-stage open-circuit detection mechanism to perform open-circuit detection at the front stage of the lighting device. Therefore, the front-stage open-circuit detection device can achieve precise open-circuit detection and isolation detection without the need for a detection resistor so as to reduce the power loss of the lighting device and meet actual requirements.

(2) In one embodiment of the present invention, the circuit design of the front-stage open-circuit detection device can execute the specialized front-stage open-circuit detection mechanism to perform open-circuit detection at the front stage of the lighting device in order to reduce the power loss of the lighting device. As such, the front-stage open-circuit detection device is highly suitable for application in low-output-power LED lighting devices and can achieve accurate detection results. Therefore, the application of the front-stage open-circuit detection device can be more comprehensive and flexible in use.

(3) In one embodiment of the present invention, the voltage divider circuit of the front-stage open-circuit detection device includes a main resistor and an auxiliary resistor. One end of the main resistor is connected to the adjustment circuit, the other end of the main resistor is connected to one end of the auxiliary resistor and the controller. The other end of the auxiliary resistor is connected to a grounding point. The auxiliary resistor may be a variable resistor. The voltage signal generated by the voltage divider circuit causes the controller to read a voltage value substantially equal to the preset minimum measurement value of the controller when the lighting device enters the open-circuit state. The controller generates the state signal indicating the open-circuit state. The voltage signal generated by the voltage divider circuit causes the controller to read a voltage value greater than the preset minimum measurement value of the controller when the lighting device is connected to a load and enters the normal operating state. The controller generates the state signal indicating the normal operating state. The circuit design of the voltage divider circuit allows the controller to effectively determine not only the open-circuit state of the lighting device without any load but also the open-circuit state of the lighting device with a dummy load. Therefore, the functionality of the front-stage open-circuit detection device can be effectively enhanced, which can conform to the requirements of different applications.

(4) In one embodiment of the present invention, the front-stage open-circuit detection device further includes an auxiliary capacitor. One end of the auxiliary capacitor is connected to the other end of the main resistor, one end of the auxiliary resistor, and the controller. The other end of the auxiliary capacitor is connected to the grounding point. The auxiliary capacitor can effectively provide voltage stabilization and filtering functions for the voltage signal output by the voltage divider circuit. Therefore, the accuracy of the front-stage open-circuit detection device can be further improved.

(5) In one embodiment of the present invention, the design of the front-stage open-circuit detection device is simple and can be applied to low-output-power LED lighting devices. Therefore, the front-stage open-circuit detection device can achieve the desired functionality without significantly increasing costs, and the application thereof can be more extensive. As a result, the practicality of the front-stage open-circuit detection device can be greatly enhanced so as to align with future development trends.

Further scope of applicability of the present application will become more apparent from the detailed description given hereinafter. However, it should be understood that the detailed description and specific examples, while indicating exemplary embodiments of the present invention, are given by way of illustration only, since various changes and modifications within the spirit and scope of the present invention will become apparent to those skilled in the art from this detailed description.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 is a circuit diagram of a front-stage open-circuit detection device in accordance with one embodiment of the present invention.

FIG. 2 is a schematic view of the front-stage open-circuit detection device receiving a control signal from a lighting device in accordance with one embodiment of the present invention.

FIG. 3 is a circuit diagram of a front-stage open-circuit detection device in accordance with another embodiment of the present invention.

FIG. 4 is a circuit diagram of a front-stage open-circuit detection device in accordance with still another embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. It should be understood that, when it is described that an element is “coupled” or “connected” to another element, the element may be “directly coupled” or “directly connected” to the other element or “coupled” or “connected” to the other element through a third element. In contrast, it should be understood that, when it is described that an element is “directly coupled” or “directly connected” to another element, there are no intervening elements.

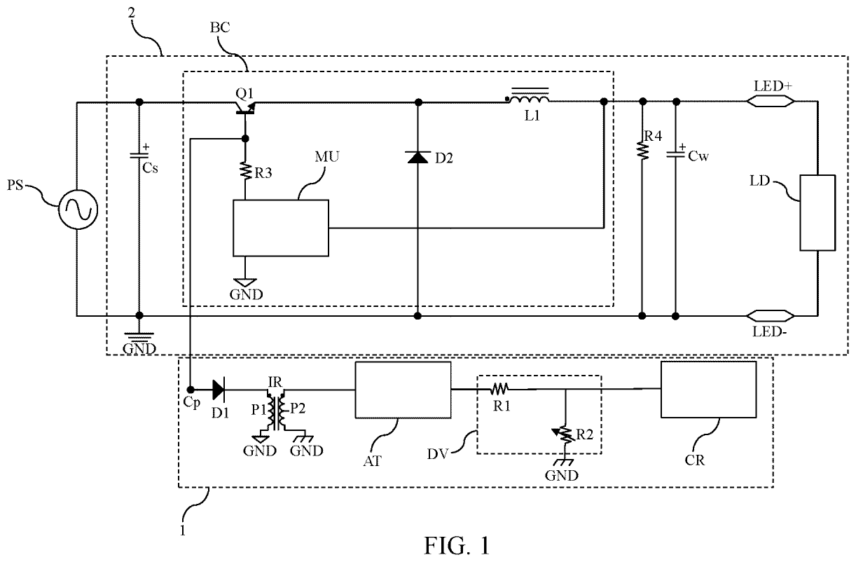

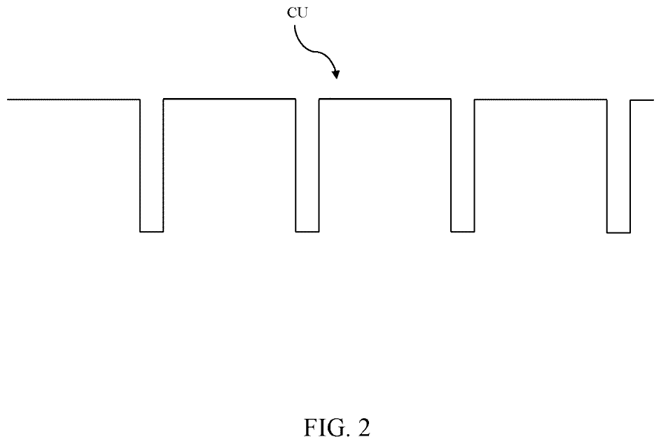

Please refer to FIG. 1 and FIG. 2. FIG. 1 is a circuit diagram of a front-stage open-circuit detection device in accordance with one embodiment of the present invention. FIG. 2 is a schematic view of the front-stage open-circuit detection device receiving a control signal from a lighting device in accordance with one embodiment of the present invention. As shown in FIG. 1 and FIG. 2., the front-stage open-circuit detection device 1 includes a diode D1, an isolation transformer IR, an adjustment circuit AT, a voltage divider circuit DV, and a controller CR. The front-stage open-circuit detection device 1 is connected to the lighting device 2 to perform open-circuit detection. The lighting device 2 may be a light-emitting diode (LED) lighting device. The lighting device 2 includes an input capacitor Cs, a converter BC, an output resistor R4, an output capacitor Cw, a positive output terminal LED+, a negative output terminal LED−, and a load LD. The load LD may be one or more LEDs. The input capacitor Cs (input terminal) of the lighting device 2 is connected to an external power source PS, which may be an alternating current (AC) power source, such as a utility power, a generator, or other similar power sources. In this embodiment, the converter BC may be a buck converter, which includes a control switch Q1, a resistor R3, a control chip MU, a diode D2, and an inductor L1. The circuit structure of the converter BC should be well-known to those skilled in the art and will not be described in detail here.

The isolation transformer IR has a detection point Cp, a primary side P1, and a secondary side P2. The detection point Cp is connected to the control switch Q1 of the converter BC and the diode D1 of the lighting device 2. In this embodiment, the control switch Q1 may be a metal-oxide-semiconductor field-effect transistor (MOSFET), and the detection point Cp is connected to the gate of the control switch Q1 to receive the control signal of the control switch Q1 (the waveform CU of the control signal is shown in FIG. 2). In another embodiment, the control switch Q1 may also be a bipolar junction transistor (BUT) or other similar components. Then, the primary side P1 couples the control signal to the secondary side P2 to generate a coupled signal. In one embodiment, the isolation transformer IR may be a high-frequency isolation transformer.

The adjustment circuit AT is connected to the primary side P1 of the isolation transformer IR. The adjustment circuit AT rectifies and filters the coupled signal to generate an adjusted signal. In one embodiment, the adjustment circuit AT may include a rectification circuit and filtering circuit to provide rectification and filtering functions. The circuit structure of the adjustment circuit AT should be well-known to those skilled in the art and will not be described in detail here.

The voltage divider circuit DV is connected to the adjustment circuit AT. The voltage divider circuit DV divides the voltage of the adjusted signal to generate a voltage signal. The voltage divider circuit DV includes a main resistor R1 and an auxiliary resistor R2. One end of the main resistor R1 is connected to the adjustment circuit AT, and the other end of the main resistor R1 is connected to one end of the auxiliary resistor R2 and the controller CR. The other end of the auxiliary resistor R2 is connected to a grounding point GND. In this embodiment, the auxiliary resistor R2 may be a variable resistor. In another embodiment, the auxiliary resistor R2 may be one of various currently available resistors.

The controller CR is connected to the voltage divider circuit DV. The controller CR receives the voltage signal and reads the voltage signal to generate a state signal. The aforementioned voltage signal may be a sampled value (AD value) of an oscillating voltage. The aforementioned state signal may indicate the open-circuit state or the normal operating state. In one embodiment, the controller CR may be a microcontroller (MCU), a central processing unit (CPU), an application-specific integrated circuit (ASIC), a field-programmable gate array (FPGA), or other similar components.

As shown in FIG. 2, when the lighting device 2 is connected to the load LD, the duty cycle of the control signal is high. Therefore, the voltage value of the coupled signal is also high, so the voltage signal (AD value) read by the controller CR is also high. At this time, the controller CR generates the state signal indicating the normal operating state. Conversely, when the lighting device 2 is connected to a dummy load or no load, the duty cycle of the control signal is low. Therefore, the voltage value of the coupled signal is also low, so the voltage signal (AD value) read by the controller CR is also low. At this time, the controller CR generates the state signal indicating the open-circuit state (in this embodiment, the open-circuit state refers to the lighting device 2 being connected to a dummy load or no load). Therefore, through the aforementioned front-stage open-circuit detection mechanism, the front-stage open-circuit detection device can achieve precise open-circuit detection.

The auxiliary resistor R2 can be appropriately adjusted. Thus, the voltage signal generated by the voltage divider circuit DV enables the controller CR to read a voltage value substantially equal to the preset minimum measurement value of the controller CR when the lighting device 2 enters the open-circuit state. Additionally, the voltage signal generated by the voltage divider circuit DV enables the controller CR to read a voltage value greater than the preset minimum measurement value of the controller CR when the lighting device 2 is connected to the load LD and enters the normal operating state. At this time, the controller CR generates the state signal indicating the normal operating state. In one embodiment, the preset minimum measurement value may be 0.3V. In another embodiment, the preset minimum measurement value may be 0.4V, 0.5V, 0.6V, etc., which may vary depending on the model or specifications of the controller CR.

As described above, in this embodiment, the front-stage open-circuit detection device 1 includes the isolation transformer IR, the adjustment circuit AT, the voltage divider circuit DV, and the controller CR. The isolation transformer IR has a detection point Cp, a primary side P1, and a secondary side P2. The detection point Cp receives the control signal of the control switch Q1 of the converter BC of the lighting device 2, and the primary side P1 couples the control signal to the secondary side P2 to generate a coupled signal. The adjustment circuit AT rectifies and filters the coupled signal to generate an adjusted signal. The voltage divider circuit DV divides the voltage of the adjusted signal to generate a voltage signal. The controller CR receives the voltage signal to generate a state signal. The circuit design of the front-stage open-circuit detection device 1 can execute a specialized front-stage open-circuit detection mechanism to perform open-circuit detection at the front stage of the lighting device 2. Therefore, the front-stage open-circuit detection device 1 can achieve precise open-circuit detection and isolation detection without the need for a detection resistor, which can reduce the power loss of the lighting device 2 and meet actual requirements.

Additionally, in this embodiment, the circuit design of the front-stage open-circuit detection device 1 can execute the specialized front-stage open-circuit detection mechanism to perform open-circuit detection at the front stage of the lighting device 2, which can reduce the power loss of the lighting device 2. As such, the front-stage open-circuit detection device 1 is highly suitable for application in low-output-power LED lighting devices and can achieve accurate detection results. Therefore, the application of the front-stage open-circuit detection device 1 can be more comprehensive and flexible in use.

Furthermore, in this embodiment, the voltage divider circuit DV of the front-stage open-circuit detection device 1 includes the main resistor R1 and the auxiliary resistor R2. One end of the main resistor R1 is connected to the adjustment circuit AT, and the other end of the main resistor R1 is connected to one end of the auxiliary resistor R2 and the controller CR. The other end of the auxiliary resistor R2 is connected to the grounding point GND. The auxiliary resistor R2 may be a variable resistor. The voltage signal generated by the voltage divider circuit DV enables the controller CR to read a voltage value substantially equal to the preset minimum measurement value of the controller CR when the lighting device 2 enters the open-circuit state, and the controller CR generates the state signal indicating the open-circuit state. The voltage signal generated by the voltage divider circuit DV enables the controller CR to read a voltage value greater than the preset minimum measurement value of the controller CR when the lighting device 2 is connected to the load LD and enters the normal operating state, and the controller CR generates the state signal indicating the normal operating state. The circuit design of the voltage divider circuit DV allows the controller CR to effectively determine not only the open-circuit state of the lighting device 2 without any load but also the open-circuit state of the lighting device 2 with a dummy load. Therefore, the functionality of the front-stage open-circuit detection device 1 can be effectively enhanced with a view to meeting the requirements of different applications.

The embodiment just exemplifies the present invention and is not intended to limit the scope of the present invention; any equivalent modification and variation according to the spirit of the present invention is to be also included within the scope of the following claims and their equivalents.

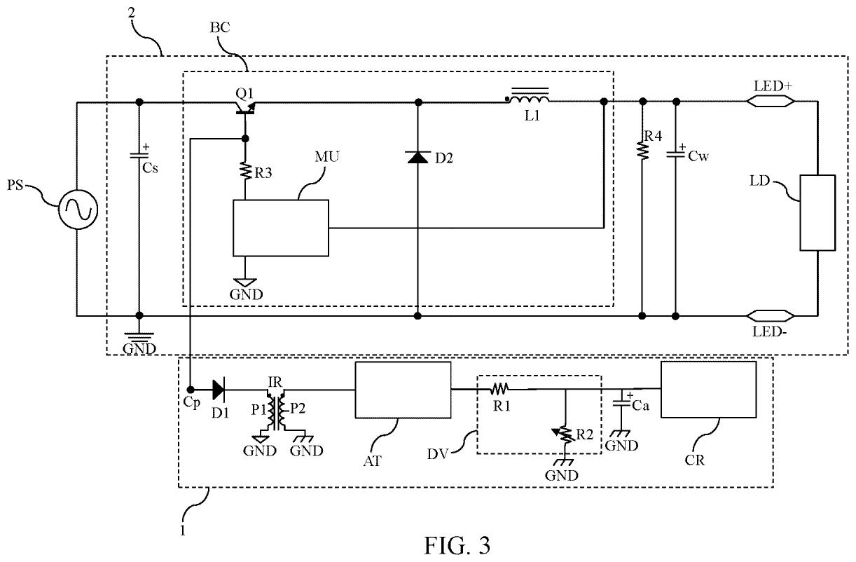

Please refer to FIG. 3, which is a circuit diagram of a front-stage open-circuit detection device in accordance with another embodiment of the present invention. As shown in FIG. 3, the front-stage open-circuit detection device 1 includes a diode D1, an isolation transformer IR, an adjustment circuit AT, a voltage divider circuit DV, and a controller CR. The front-stage open-circuit detection device 1 is connected to the lighting device 2 to perform open-circuit detection. The lighting device 2 may be an LED lighting device. The lighting device 2 includes an input capacitor Cs, a converter BC, an output resistor R4, an output capacitor Cw, a positive output terminal LED+, a negative output terminal LED−, and a load LD.

The isolation transformer IR has a detection point Cp, a primary side P1, and a secondary side P2. The detection point Cp is connected to the control switch Q1 of the converter BC and the diode D1 of the lighting device 2. The control switch Q1 may be a MOSFET, and the detection point Cp is connected to the gate of the control switch Q1 to receive the control signal of the control switch Q1 (the waveform CU of the control signal is shown in FIG. 2). Then, the primary side P1 couples the control signal to the secondary side P2 to generate a coupled signal.

The adjustment circuit AT is connected to the primary side P1 of the isolation transformer IR. The adjustment circuit AT rectifies and filters the coupled signal to generate an adjusted signal.

The voltage divider circuit DV is connected to the adjustment circuit AT. The voltage divider circuit DV divides the voltage of the adjusted signal to generate a voltage signal. The voltage divider circuit DV includes a main resistor R1 and an auxiliary resistor R2. One end of the main resistor R1 is connected to the adjustment circuit AT, and the other end of the main resistor R1 is connected to one end of the auxiliary resistor R2 and the controller CR. The other end of the auxiliary resistor R2 is connected to a grounding point GND.

The controller CR is connected to the voltage divider circuit DV. The controller CR receives the voltage signal and reads the voltage signal to generate a state signal.

The aforementioned components are similar to those in the previous embodiment, so will not be described in detail here. The difference between this embodiment and the previous embodiment is that the front-stage open-circuit detection device 1 in this embodiment further includes an auxiliary capacitor Ca. One end of the auxiliary capacitor Ca is connected to the other end of the main resistor R1, one end of the auxiliary resistor R2, and the controller CR, while the other end of the auxiliary capacitor Ca is connected to the grounding point GND. The auxiliary capacitor Ca can effectively provide voltage stabilization and filtering functions for the voltage signal output by the voltage divider circuit DV. Therefore, the accuracy of the front-stage open-circuit detection device 1 can be further improved.

As mentioned earlier, in this embodiment, the front-stage open-circuit detection device 1 further includes the auxiliary capacitor Ca, which can effectively provide voltage stabilization and filtering functions for the voltage signal output by the voltage divider circuit DV. Therefore, the accuracy of the front-stage open-circuit detection device 1 can be further improved. The design of the front-stage open-circuit detection device 1 is simple and can be applied to low-output-power LED lighting devices. Therefore, the front-stage open-circuit detection device 1 can achieve the desired functionality without significantly increasing costs, and the application thereof can be more comprehensive. As a result, the practicality of the front-stage open-circuit detection device 1 can be greatly enhanced with a view to aligning with future development trends.

The embodiment just exemplifies the present invention and is not intended to limit the scope of the present invention; any equivalent modification and variation according to the spirit of the present invention is to be also included within the scope of the following claims and their equivalents.

It is worthy to point out that the currently available open-circuit detection method for LED lighting devices involves adding a detection resistor to the rear stage of the lighting device and determining whether the LED lighting device is in the open-circuit state by measuring the voltage drop across the detection resistor. Although this method is simple, this method increases the power loss of the LED lighting device and reduces the efficiency thereof. Since the output power of LED lighting devices is relatively low, increasing the resistance value of the aforementioned resistor would lead to a particularly noticeable increase in power loss. Conversely, if the resistance value of the resistor is not increased, the voltage drop across the resistor would be too small, making it prone to erroneous measurements. Therefore, the currently available open-circuit detection method is not suitable for LED lighting devices. By contrast, according to one embodiment of the present invention, the front-stage open-circuit detection device includes an isolation transformer, an adjustment circuit, a voltage divider and a controller. The isolation transformer has a detection point, a primary side, and a secondary side. The detection point receives a control signal from the control switch of the converter in a lighting device. The primary side couples the control signal to the secondary side to generate a coupled signal. The adjustment circuit rectifies and filters the coupled signal to generate an adjusted signal. The voltage divider circuit divides the adjusted signal to generate a voltage signal. The controller receives the voltage signal and generates a state signal. The circuit design of the front-stage open-circuit detection device can execute a specialized front-stage open-circuit detection mechanism to perform open-circuit detection at the front stage of the lighting device. Therefore, the front-stage open-circuit detection device can achieve precise open-circuit detection and isolation detection without the need for a detection resistor so as to reduce the power loss of the lighting device and meet actual requirements.

Also, according to one embodiment of the present invention, the circuit design of the front-stage open-circuit detection device can execute the specialized front-stage open-circuit detection mechanism to perform open-circuit detection at the front stage of the lighting device in order to reduce the power loss of the lighting device. As such, the front-stage open-circuit detection device is highly suitable for application in low-output-power LED lighting devices and can achieve accurate detection results. Therefore, the application of the front-stage open-circuit detection device can be more comprehensive and flexible in use.

Further, according to one embodiment of the present invention, the voltage divider circuit of the front-stage open-circuit detection device includes a main resistor and an auxiliary resistor. One end of the main resistor is connected to the adjustment circuit, the other end of the main resistor is connected to one end of the auxiliary resistor and the controller. The other end of the auxiliary resistor is connected to a grounding point. The auxiliary resistor may be a variable resistor. The voltage signal generated by the voltage divider circuit causes the controller to read a voltage value substantially equal to the preset minimum measurement value of the controller when the lighting device enters the open-circuit state. The controller generates the signal state indicating the open-circuit state. The voltage signal generated by the voltage divider circuit causes the controller to read a voltage value greater than the preset minimum measurement value of the controller when the lighting device is connected to a load and enters the normal operating state. The controller generates the state signal indicating the normal operating state. The circuit design of the voltage divider circuit allows the controller to effectively determine not only the open-circuit state of the lighting device without any load but also the open-circuit state of the lighting device with a dummy load. Therefore, the functionality of the front-stage open-circuit detection device can be effectively enhanced, which can conform to the requirements of different applications.

Moreover, according to one embodiment of the present invention, the front-stage open-circuit detection device further includes an auxiliary capacitor. One end of the auxiliary capacitor is connected to the other end of the main resistor, one end of the auxiliary resistor, and the controller. The other end of the auxiliary capacitor is connected to the grounding point. The auxiliary capacitor can effectively provide voltage stabilization and filtering functions for the voltage signal output by the voltage divider circuit. Therefore, the accuracy of the front-stage open-circuit detection device can be further improved.

Furthermore, according to one embodiment of the present invention, the design of the front-stage open-circuit detection device is simple and can be applied to low-output-power LED lighting devices. Therefore, the front-stage open-circuit detection device can achieve the desired functionality without significantly increasing costs, and the application thereof can be more extensive. As a result, the practicality of the front-stage open-circuit detection device can be greatly enhanced so as to align with future development trends. As set forth above, the front-stage open-circuit detection device according to the embodiments of the present invention can achieve great technical effects.

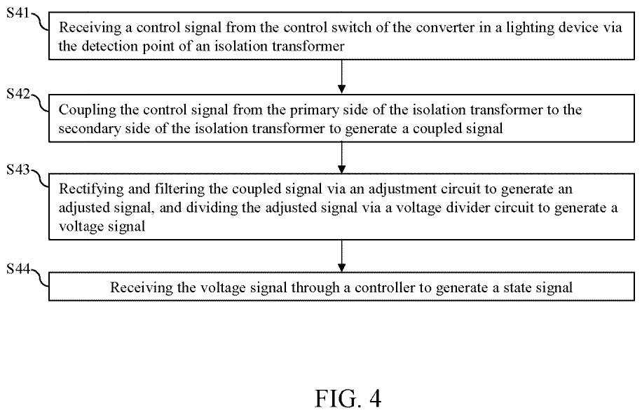

Please refer to FIG. 4, which is a circuit diagram of a front-stage open-circuit detection device in accordance with still another embodiment of the present invention. As shown in FIG. 4, the front-stage open-circuit detection method in this embodiment includes the following steps:

Step S41: receiving a control signal from the control switch of the converter in a lighting device via the detection point of an isolation transformer.

Step S42: coupling the control signal from the primary side of the isolation transformer to the secondary side of the isolation transformer to generate a coupled signal.

Step S43: rectifying and filtering the coupled signal via an adjustment circuit to generate an adjusted signal, and dividing the adjusted signal via a voltage divider circuit to generate a voltage signal.

Step S44: receiving the voltage signal through a controller to generate a state signal. The voltage signal generated by the voltage divider circuit causes the controller to read a voltage value substantially equal to the preset minimum measurement value of the controller when the lighting device enters the open-circuit state. The controller generates the state signal indicating the open-circuit state. The voltage signal generated by the voltage divider circuit causes the controller to read a voltage value greater than the preset minimum measurement value of the controller when the lighting device is connected to a load and enters the normal operating state. The controller generates the state signal indicating the normal operating state.

The embodiment just exemplifies the present invention and is not intended to limit the scope of the present invention; any equivalent modification and variation according to the spirit of the present invention is to be also included within the scope of the following claims and their equivalents.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

To sum up, according to one embodiment of the present invention, the front-stage open-circuit detection device includes an isolation transformer, an adjustment circuit, a voltage divider and a controller. The isolation transformer has a detection point, a primary side, and a secondary side. The detection point receives a control signal from the control switch of the converter in a lighting device. The primary side couples the control signal to the secondary side to generate a coupled signal. The adjustment circuit rectifies and filters the coupled signal to generate an adjusted signal. The voltage divider circuit divides the adjusted signal to generate a voltage signal. The controller receives the voltage signal and generates a state signal. The circuit design of the front-stage open-circuit detection device can execute a specialized front-stage open-circuit detection mechanism to perform open-circuit detection at the front stage of the lighting device. Therefore, the front-stage open-circuit detection device can achieve precise open-circuit detection and isolation detection without the need for a detection resistor so as to reduce the power loss of the lighting device and meet actual requirements.

Also, according to one embodiment of the present invention, the circuit design of the front-stage open-circuit detection device can execute the specialized front-stage open-circuit detection mechanism to perform open-circuit detection at the front stage of the lighting device in order to reduce the power loss of the lighting device. As such, the front-stage open-circuit detection device is highly suitable for application in low-output-power LED lighting devices and can achieve accurate detection results. Therefore, the application of the front-stage open-circuit detection device can be more comprehensive and flexible in use.

Further, according to one embodiment of the present invention, the voltage divider circuit of the front-stage open-circuit detection device includes a main resistor and an auxiliary resistor. One end of the main resistor is connected to the adjustment circuit, the other end of the main resistor is connected to one end of the auxiliary resistor and the controller. The other end of the auxiliary resistor is connected to a grounding point. The auxiliary resistor may be a variable resistor. The voltage signal generated by the voltage divider circuit causes the controller to read a voltage value substantially equal to the preset minimum measurement value of the controller when the lighting device enters the open-circuit state. The controller generates the state signal indicating the open-circuit state. The voltage signal generated by the voltage divider circuit causes the controller to read a voltage value greater than the preset minimum measurement value of the controller when the lighting device is connected to a load and enters the normal operating state. The controller generates the state signal indicating the normal operating state. The circuit design of the voltage divider circuit allows the controller to effectively determine not only the open-circuit state of the lighting device without any load but also the open-circuit state of the lighting device with a dummy load. Therefore, the functionality front-stage open-circuit detection device can be effectively enhanced, which can conform to the requirements of different applications.

Moreover, according to one embodiment of the present invention, the front-stage open-circuit detection device further includes an auxiliary capacitor. One end of the auxiliary capacitor is connected to the other end of the main resistor, one end of the auxiliary resistor, and the controller. The other end of the auxiliary capacitor is connected to the grounding point. The auxiliary capacitor can effectively provide voltage stabilization and filtering functions for the voltage signal output by the voltage divider circuit. Therefore, the accuracy of the front-stage open-circuit detection device can be further improved.

Furthermore, according to one embodiment of the present invention, the design of the front-stage open-circuit detection device is simple and can be applied to low-output-power LED lighting devices. Therefore, the front-stage open-circuit detection device can achieve the desired functionality without significantly increasing costs, and the application thereof can be more extensive. As a result, the practicality of the front-stage open-circuit detection device can be greatly enhanced so as to align with future development trends.

It will be apparent to those skilled in the art that various modifications and variations can be made to the disclosed embodiments. It is intended that the specification and examples be considered as exemplary only, with a true scope of the present invention being indicated by the following claims and their equivalents.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A front-stage open-circuit detection device, comprising:
an isolation transformer having a detection point, a primary side, and a secondary side, wherein the detection point is configured to receive a control signal from a control switch of a converter in a lighting device, and the primary side is configured to couple the control signal to the secondary side to generate a coupled signal;
an adjustment circuit configured to rectify and filter the coupled signal to generate an adjusted signal;
a voltage divider circuit configured to divide the adjusted signal to generate a voltage signal; and
a controller configured to receive the voltage signal and generate a state signal.

2. The front-stage open-circuit detection device as claimed in claim 1, wherein the voltage divider circuit comprises a main resistor and an auxiliary resistor, wherein one end of the main resistor is connected to the adjustment circuit, another end of the main resistor is connected to one end of the auxiliary resistor and the controller, and another end of the auxiliary resistor is connected to a grounding point.

3. The front-stage open-circuit detection device as claimed in claim 2, wherein the auxiliary resistor is a variable resistor.

4. The front-stage open-circuit detection device as claimed in claim 2, further comprising an auxiliary capacitor, wherein one end of the auxiliary capacitor is connected to another end of the main resistor, one end of the auxiliary resistor, and the controller, and another end of the auxiliary capacitor is connected to the grounding point.

5. The front-stage open-circuit detection device as claimed in claim 1, wherein the voltage signal generated by the voltage divider circuit causes the controller to read a voltage value substantially equal to a preset minimum measurement value of the controller when the lighting device enters an open-circuit state, and the controller is configured to generate the state signal indicating the open-circuit state.

6. The front-stage open-circuit detection device as claimed in claim 1, wherein the voltage signal generated by the voltage divider circuit causes the controller to read a voltage value greater than a preset minimum measurement value of the controller when the lighting device is connected to a load and enters a normal operating state, and the controller is configured to generate the state signal indicating the normal operating state.

7. A front-stage open-circuit detection method, comprising:
receiving a control signal from a control switch of a converter in a lighting device via a detection point of an isolation transformer;
coupling the control signal from a primary side of the isolation transformer to a secondary side of the isolation transformer to generate a coupled signal;
rectifying and filtering the coupled signal via an adjustment circuit to generate an adjusted signal;
dividing the adjusted signal via a voltage divider circuit to generate a voltage signal; and
receiving the voltage signal through a controller to generate a state signal.

8. The front-stage open-circuit detection method as claimed in claim 7, wherein the voltage divider circuit comprises a main resistor and an auxiliary resistor, wherein one end of the main resistor is connected to the adjustment circuit, another end of the main resistor is connected to one end of the auxiliary resistor and the controller, and another end of the auxiliary resistor is connected to a grounding point.

9. The front-stage open-circuit detection method as claimed in claim 7, wherein the voltage signal generated by the voltage divider circuit causes the controller to read a voltage value substantially equal to a preset minimum measurement value of the controller when the lighting device enters an open-circuit state, and the controller is configured to generate the state signal indicating the open-circuit state.

10. The front-stage open-circuit detection method as claimed in claim 7, wherein the voltage signal generated by the voltage divider circuit causes the controller to read a voltage value greater than a preset minimum measurement value of the controller when the lighting device is connected to a load and enters a normal operating state, and the controller is configured to generate the state signal indicating the normal operating state.
